(19) United States
(12) Patent Application Publication
(10) Pub. No.: US 2026/0363022 A1
(43) Pub. Date: Nov. 12, 2026

(54) LOAD PORT, AND LID CLOSED STATE DETERMINATION METHOD

(71) Applicant: Sinfonia Technology Co., Ltd., Tokyo (JP)

(72) Inventors: Tomoya Mizutani, Tokyo (JP); Shogo Shirakawa, Tokyo (JP); Izumi Ito, Tokyo (JP)

(73) Assignee: Sinfonia Technology Co., Ltd., Tokyo (JP)

(21) Appl. No.: 19/130,707

(22) PCT Filed: Oct. 27, 2023
(86) PCT No.: PCT/JP2023/038976

§ 371 Date: Jul. 31, 2025

(30) Foreign Application Priority Data
Nov. 17, 2022 (JP) 2022-183859

(51) Int. Cl. H10P 72/30; H10P 72/10

(52) U.S. Cl. CPC H10P 72/3406; H10P 72/1922; H10P 72/3408

(57) ABSTRACT

A load port opens and closes a FOUP including a FOUP body and a lid. The load port includes a base, a door mechanism, and a controller. The door mechanism includes a door body, an adsorption holder, latch keys, a motor, and an open sensor. The controller executes a closing process of moving the door body to a closing position, and a checking process. The checking process is a process of moving the door body from the closing position to the opening position in a state in which the lid is held by the adsorption holder, and determining whether or not the lid is normally closed based on information acquired by the open sensor.

### TECHNICAL FIELD

The present disclosure relates to a load port that opens and closes a lid of a container, and a lid closed state determination method in the load port.

### BACKGROUND

Patent Document 1 discloses a cassette station (hereinafter referred to as load port) for opening and closing a lid of a cassette (hereinafter referred to as container) accommodating wafers. The container includes a container body having an opening formed on a side surface thereof and a lid configured to open and close the opening. The lid includes an engagement claw that engages with engagement holes formed near the opening of the container body, and a latch mechanism (hereinafter referred to as locking mechanism) for extending and contracting the engagement claw. The load port includes a moving mechanism for moving the container between a docked position and an undocked position, a partition wall having an opening through which the lid can pass, a door mechanism for attaching and detaching the lid of the container disposed near the opening of the partition wall to and from the container body, and a controller. The door mechanism includes an adsorption holder, a key, and a mover. When opening the lid, the door mechanism adsorbs and holds the lid with the adsorption holder, operates the locking mechanism by the key to contract the engagement claw (i.e., unlocks the lid), and then separates the held lid from the container body by the mover. In addition, when closing the lid, the door mechanism blocks the opening of the container body with the held lid, operates the locking mechanism to extend the engagement claw (i.e., locks the lid), and then releases the adsorption of the lid.

When the container is transferred to another location without the lid being normally closed, the lid may fall off from the container body, for example, during the transfer of the container. In addition, the wafers accommodated in the container may fall out of the container. Therefore, the load port disclosed in Patent Document 1 is configured to perform an operation to check whether or not the lid is normally closed. More specifically, after locking and releasing the lid by the door mechanism, the controller controls the moving mechanism to move the container once to the undocked position and again to the docked position. Further, the controller executes an operation to insert the key into the locking mechanism again and an operation to adsorb and hold the lid by the adsorption holder again. When the operations described above are performed normally, the controller determines that the lid is normally closed.

### Prior Art Document

### Patent Document

Patent Document 1: Japanese Patent Laid-open Publication No. 2014-138011

With only the above operations, even when the lid is not actually closed normally, it may be erroneously determined that the lid is normally closed. More specifically, in a case in which a hole in the locking mechanism into which the key is inserted is worn, for example, when and the lid is not normally closed and the key is inserted into the hole, it may be erroneously determined that the lid is normally closed.

In addition, since the container is once moved to the undocked position, when the lid is not normally closed, an internal space of the container may be exposed to a gas of a space outside the container and the load port (hereinafter referred to as external space). In this case, the wafers accommodated in the container may be contaminated by the gas of the external space (such as the air).

### SUMMARY

The present disclosure provides some embodiments of a technique capable of effectively checking whether or not a lid is normally closed in a container without exposing an internal space of the container to a gas of an external space.

A load port of a first aspect includes: a partition wall configured to connect an internal space of a container body, which has a side opening formed on a side surface of the container body and accommodates a transfer target, to a transfer space in which transfer of the transfer target is performed, wherein the partition wall has an opening through which a lid for opening and closing the side opening can pass, and is configured to separate the internal space and the transfer space from an external space; a door mechanism configured to attach and detach the lid with respect to the container body; and a controller. The door mechanism includes: a door body configured to open and close the opening; a holder configured to hold the lid on the door body; a key configured to lock and unlock a locking mechanism provided on the lid to cause the lid to engage with the container body; a mover configured to move the door body between a closing position where the door body closes the opening and an opening position where the door body opens the opening; and an information acquisitor configured to acquire information on a position of the door body. The controller performs: a closing process of moving the door body to the closing position by the mover in a state in which the lid is held by the holder, and locking the locking mechanism by the key; and after the closing process, a checking process of moving the door body from the closing position to the opening position in a state in which the lid is held by the holder, and determining whether or not the lid is normally closed based on the information acquired by the information acquisitor.

According to the first aspect, by performing, with respect to a container having a container body and a lid, a checking process of pulling the lid by the door body, it is possible to check whether or not the lid is normally closed after the closing process. Further, since such checking is performed without moving the container, it is possible to prevent an internal space of the container from being exposed to a gas of an external space. Therefore, it is possible to effectively check whether or not the lid is normally closed in the container without exposing the internal space of the container to the gas of the external space.

The load port of a second aspect is characterized in that, in the first aspect, the information acquisitor includes an open detector configured to detect whether or not the door body is located at the opening position, and in the checking process, the controller determines that the lid is not normally closed when information indicating that the door body is located at the opening position is detected by the open detector.

According to the second aspect, in the opening process, whether or not the door body has normally reached the opening position can be determined by using the open detector. Further, the checking process can also be performed by using the open detector. That is, the open detector can be used for both the opening process and the checking process. Therefore, compared to a case where the checking process is performed using the open detector and components other than the open detector, an increase in the number of components constituting the load port can be suppressed.

The load port of a third aspect is characterized in that, in the first or second aspect, the mover is configured to change a thrust for moving the door body, and the controller applies a predetermined first thrust to the door body when performing an opening process of separating the lid from the container body, and applies a second thrust weaker than the first thrust to the door body when performing the checking process.

According to the present disclosure, a thrust is applied to the door body (and the lid) during the checking process, regardless of whether or not the lid is normally closed by the closing process. Therefore, when the lid is normally closed and the thrust is too strong, the locking mechanism may be damaged. In this regard, the third aspect can weaken the second thrust when the checking process is performed. Accordingly, it is possible to prevent the locking mechanism from being damaged.

The load port of a fourth aspect is characterized in that, in the first or second aspect, when determining that the lid is not normally closed in the checking process, the controller performs a re-closing process of unlocking the locking mechanism by the key in a state in which the lid is held by the holder, causing the door body to return to the closing position by the mover, and locking the locking mechanism by the key.

When the lid is not normally closed, an action by an operator may be required. According to the fourth aspect, even when the closing process fails to close the lid normally, the process of closing the lid can be performed again. Thus, even when the closing process fails once, no action by the operator is required when the re-closing process is successful. Therefore, an increase in operator's workload can be suppressed.

A lid closed state determination method of a fifth aspect is a method of determining whether or not a lid is normally closed in a load port that attaches and detaches, with respect to a container body accommodating a transfer target, the lid for opening and closing a side opening formed on a side surface of the container body. The load port includes: a partition wall configured to connect an internal space of the container body to a transfer space in which transfer of the transfer target is performed, wherein the partition wall has an opening through which the lid can pass, and is configured to separate the internal space and the transfer space from an external space; and a door mechanism configured to attach and detach the lid with respect to the container body. The door mechanism includes: a door body configured to open and close the opening; a holder configured to hold the lid on the door body; a key configured to lock and unlock a locking mechanism provided on the lid to cause the lid to engage with the container body; a mover configured to move the door body between a closing position where the door body closes the opening and an opening position where the door body opens the opening; and an information acquisitor configured to acquire information on a position of the door body. The method comprises: a closing process of moving the door body to the closing position by the mover in a state in which the lid is held by the holder, and locking the locking mechanism by the key; and after the closing process, a checking process of moving the door body from the closing position to the opening position in a state in which the lid is held by the holder, and determining whether or not the lid is normally closed based on the information acquired by the information acquisitor.

According to the fifth aspect, as in the first aspect, it is possible to effectively check whether or not the lid is normally closed in the container without exposing the internal space of the container to the gas in the external space.

### BRIEF DESCRIPTION OF DRAWINGS

FIG. 1 is a schematic plan view of an EFEM equipped with a load port according to the present embodiment and its surroundings.

FIG. 2 is a perspective view of a FOUP.

FIGS. 3A and 3B are views showing the FOUP as viewed from a lid side in a front-rear direction.

FIG. 4A is a perspective view of a load port, and FIG. 4B is a right side view of the load port.

FIG. 5A is a front view of the load port, and FIG. 5B is a rear view of the load port.

FIGS. 6A and 6B are explanatory views showing a lid opening/closing mechanism.

FIGS. 7A and 7B are explanatory views showing an operation of the load port.

FIGS. 8A and 8B are explanatory views showing an operation of the load port.

FIG. 9 is a block diagram showing an electrical configuration of the load port.

FIG. 10 is a flowchart showing a procedure for determining a closed state of the lid.

FIGS. 11A to 11D are explanatory views showing an operation of the load port.

### DETAILED DESCRIPTION

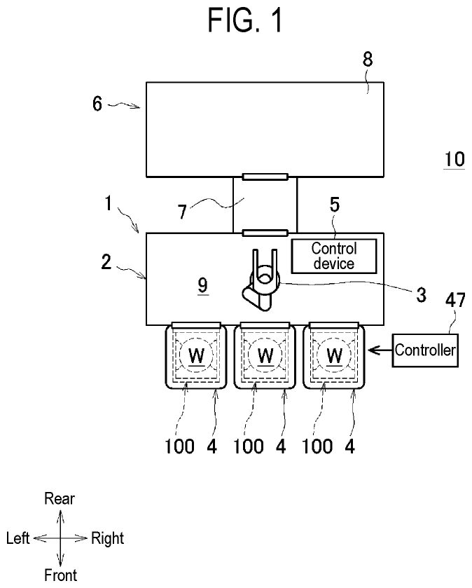

Next, an embodiment of the present disclosure will be described. For the sake of convenience of description, directions shown in FIG. 1 are defined as a front-rear direction and a left-right direction. That is, a direction along which an equipment front end module (EFEM) 1 and a processing apparatus 6 are arranged is defined as the front-rear direction. In the front-rear direction, a side of the EFEM 1 is defined as a front side. In the front-rear direction, a side of the processing apparatus 6 is defined as a rear side. A direction perpendicular to the front-rear direction, along which a plurality of load ports 4 are arranged, is defined as the left-right direction. In addition, a direction perpendicular to both the front-rear direction and the left-right direction is defined as an up-down direction (a vertical direction in which gravity acts).

### Overall Configuration of Load Port and Surroundings

The overall configuration of the load port 4 and surroundings thereof according to this embodiment will be described with reference to FIG. 1. FIG. 1 is a schematic diagram of the equipment front end module (EFEM) 1 equipped with the load ports 4 and its surroundings. As shown in FIG. 1, the EFEM 1 includes a housing 2, a transfer robot 3, the load ports 4, and a control device 5. The processing apparatus 6 is disposed on the rear side of the EFEM 1. The processing apparatus 6 is an apparatus that performs a predetermined process on a wafer W (a transfer target in the present disclosure), which is a semiconductor substrate. The predetermined process may be, for example, a process (sputtering, dry etching, or the like) performed in a vacuum chamber, or may be other processes. The EFEM 1 transfers the wafer W between a front-opening unified pod (FOUP) 100 placed on the load port 4 and the processing apparatus 6 by the transfer robot 3 disposed in a transfer space 9 in the housing 2. The FOUP 100 is a container that can accommodate a plurality of wafers W arranged vertically. The FOUP 100 is transferred by a FOUP transfer device (not shown). The FOUP 100 is delivered between the transfer device and the load port 4.

The housing 2 is a member that forms the transfer space 9 in which transfer of the wafer W is performed. The transfer space 9 is separated from an external space 10 mainly by the housing 2. The housing 2 is configured to be connected to the load ports 4 and a load lock chamber 7 of the processing apparatus 6. The transfer robot 3 is a robot configured to transfer the wafer W between the FOUP 100 and the load lock chamber 7.

The load ports 4 are arranged, for example, side by side in the left-right direction and attached to a front surface of the housing 2. Each of the load ports 4 is configured to place the FOUP 100 thereon, and configured to attach and detach a lid 102 (which will be described later) to a FOUP body 101 (which will be described later) (container body of the present disclosure) of the FOUP 100 placed thereon. Details of a configuration of the load port 4 and a configuration of the FOUP 100 will be described later.

The control device 5 is electrically connected to a controller (not shown) of the transfer robot 3, a controller 47 of the load port 4, and a controller (not shown) of the processing apparatus 6, and performs communication with the controllers described above.

The processing apparatus 6 includes, for example, the load lock chamber 7 and a process chamber 8. The load lock chamber 7 is a chamber in which the wafer W stands-by temporarily. The load lock chamber 7 is connected to the transfer space 9 formed in the housing 2. The process chamber 8 is a chamber in which a predetermined process is performed for the wafer W.

### FOUP

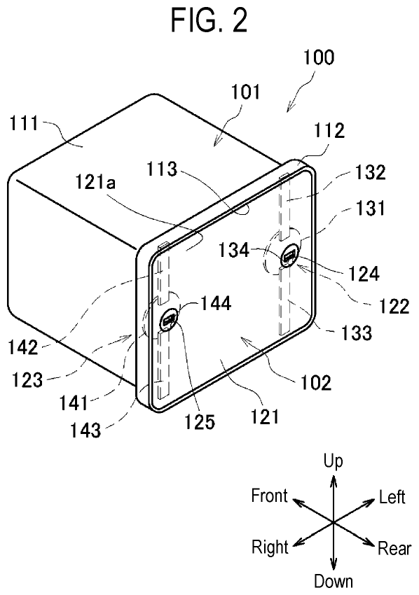

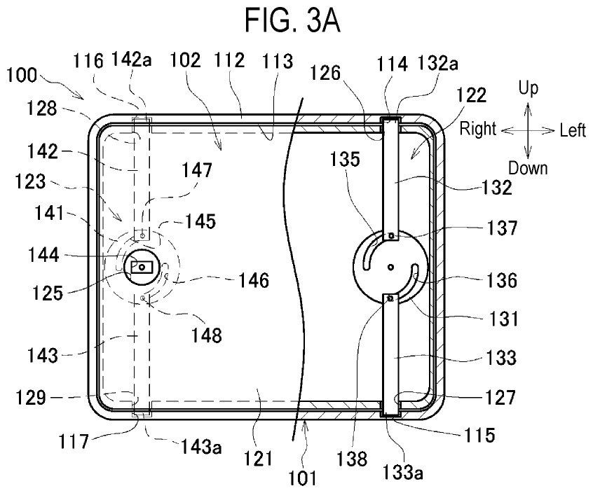

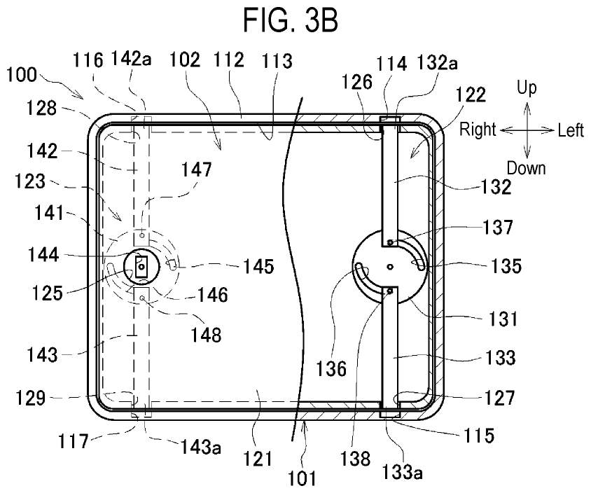

Before describing the configuration of the load port 4, the configuration of the FOUP 100 will be described with reference to FIGS. 2, 3A and 3B. FIG. 2 is a perspective view of the FOUP 100. Front-rear, left-right, up-down directions shown in FIG. 2 are directions set for the sake of convenience of description under an assumption that the FOUP 100 is placed on the load port 4 and the lid 102 is normally closed. FIGS. 3A and 3B are views of the FOUP 100 as viewed from a side of the lid 102 (i.e., a rear side) in the front-rear direction. FIG. 3A is a view showing a state in which the lid 102 is locked. In FIG. 3A, a portion of the lid 102 (a right portion in the figure) is shown in cross section. FIG. 3B is a view showing a state in which the lid 102 is unlocked. In FIG. 3B, the portion of the lid 102 (the right-side portion in the figure) is also shown in cross section.

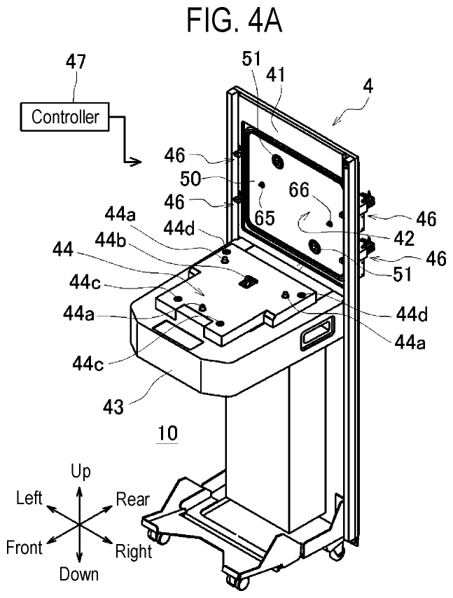

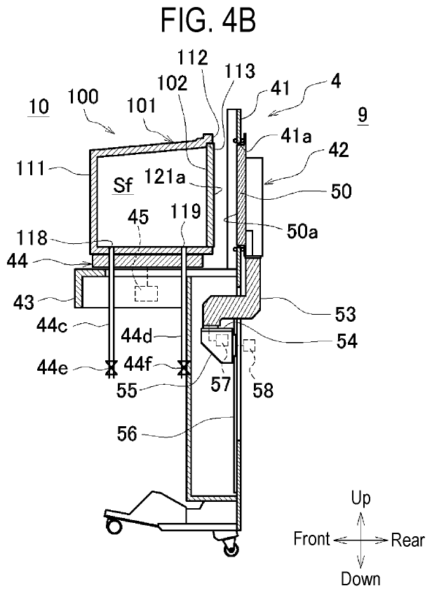

The FOUP 100 is a container having a substantially rectangular parallelepiped shape. As shown in FIG. 2, the FOUP 100 includes the FOUP body 101 and the lid 102. The FOUP body 101 has a substantially rectangular parallelepiped shape. The FOUP body 101 has an outer wall 111 that surrounds an internal space Sf (see FIG. 4B) of the FOUP 100, and an opening portion 112 provided on one side surface of the FOUP body 101. The opening portion 112 has an opening 113 (side opening in the present disclosure) having a substantially rectangular shape when viewed in the front-rear direction. As shown in FIGS. 3A and 3B, an engagement hole 114 extending upward is formed on an upper left portion of an inner circumferential surface of the opening portion 112. Similarly, an engagement hole 115 extending downward is formed on a lower left portion of the inner circumferential surface of the opening portion 112. An engagement hole 116 extending upward is formed in an upper right portion of the inner circumferential surface of the opening portion 112. An engagement hole 117 extending downward is formed in a lower right portion of the inner circumferential surface of the opening portion 112.

A gas supply valve 118 and a gas exhaust valve 119 are formed at a bottom of the FOUP body 101 (see FIG. 4B). The gas supply valve 118 is a valve for supplying an inert gas, such as nitrogen gas or the like, into the internal space Sf (see FIG. 4B) of the FOUP 100. The gas exhaust valve 119 is a valve for exhausting a gas from the internal space Sf.

The lid 102 is configured to open and close the opening portion 112. The lid 102 includes a lid body 121, a latch mechanism 122, and a latch mechanism 123. The lid body 121 is a substantially plate-shaped hollow member. The lid body 121 has an end surface 121a (a lid facing surface in the present disclosure) that can face a door body 50 to be described later in the front-rear direction. An opening 124 is formed, correspondingly to the latch mechanism 122, in a left portion of the end surface 121a at an approximately center in the up-down direction. An opening 125 is formed, correspondingly to the latch mechanism 123 in a right portion of the end surface 121a at an approximately center in the up-down direction. As shown in FIGS. 3A and 3B, an insertion hole 126, which penetrates in the up-down direction and into which an upper end portion of a locking plate 132 to be described later is inserted, is formed in an upper left portion of an outer circumferential surface of the lid body 121. An insertion hole 127, which extends in the up-down direction and into which an lower end portion of a locking plate 133 to be described later is inserted, is formed in a lower left portion of the outer circumferential surface of the lid body 121. An insertion hole 128, which extends in the up-down direction and into which an upper end portion of a locking plate 142 to be described later is inserted, is formed in an upper right portion of the outer circumferential surface of the lid body 121. An insertion hole 129, which extends in the up-down direction and into which a lower end portion of a locking plate 143 to be described later is inserted, is formed in a lower right portion of the outer circumferential surface of the lid body 121.

The latch mechanisms 122 and 123 (locking mechanism in the present disclosure) are mechanisms configured to lock and unlock the lid 102. The latch mechanism 122 is provided in a left portion of the lid body 121. The latch mechanism 122 includes a rotary plate 131, the locking plate 132, and the locking plate 133. Substantially entireties of the rotary plate 131, the locking plate 132, and the locking plate 133 are accommodated in an internal space of the lid body 121. The rotary plate 131 is a substantially disk-shaped member. The rotary plate 131 is provided, correspondingly to the opening 124, on the left portion of the lid body 121 at a substantially center in the up-down direction. The rotary plate 131 is attached to the lid body 121 so as to be rotatable about a rotation axis extending in the front-rear direction. A keyhole 134 (see FIG. 2) having, for example, a substantially rectangular shape when viewed in the front-rear direction, is formed in a substantially central portion of a rear end surface of the rotary plate 131. The rotary plate 131 can rotate between a lock position (see FIG. 3A) and an unlock position (see FIG. 3B) by being rotated by a latch key 65 (a key in the present disclosure), which will be described later, inserted into the keyhole 134. Front cams 135 and 136 are formed on the rear end surface of the rotary plate 131. The front cam 135 is, for example, a groove-shaped cam formed in an upper portion of the rear end surface of the rotary plate 131. The front cam 135 is formed to extend clockwise in a circumferential direction of the rotary plate 131 and to extend inward in a radial direction of the rotary plate 131. The front cam 136 is, for example, a groove-shaped cam formed in a lower portion of the rear end surface of the rotary plate 131. The front cam 136 is formed to extend clockwise in the circumferential direction of the rotary plate 131 and to extend inward in the radial direction of the rotary plate 131.

The locking plate 132 is a member that is engaged with an upper end portion of the opening portion 112 to fix the lid 102 to the FOUP body 101 (i.e., to close the lid). The locking plate 132 is, for example, a plate-shaped member extending in the up-down direction. A lower end portion of the locking plate 132 is connected to the rotary plate 131 via a cam follower 137 extending in the front-rear direction. The cam follower 137 is inserted into the front cam 135. An engagement claw 132a to be inserted into the engagement hole 114 is formed in an upper end portion of the locking plate 132. The engagement claw 132a is located in the engagement hole 114 (engaged position) when the rotary plate 131 is located in the lock position (see FIG. 3A). The engagement claw 132a is located outside the engagement hole 114 (released position) when the rotary plate 131 is located in the unlock position (see FIG. 3B).

The locking plate 133 is a member that is engaged with a lower end portion of the opening portion 112 to engage the lid 102 with the opening portion 112. The locking plate 133 is, for example, a plate-shaped member extending in the up-down direction. An upper end portion of the locking plate 133 is connected to the rotary plate 131 via a cam follower 138 extending in the front-rear direction. The cam follower 138 is inserted into the front cam 136. An engagement claw 133a to be inserted into the engagement hole 115 is formed in a lower end portion of the locking plate 133. The engagement claw 133a is located in the engagement hole 115 (engaged position) when the rotary plate 131 is located in the lock position (see FIG. 3A). The engagement claw 133a is located outside the engagement hole 115 (released position) when the rotary plate 131 is located in the unlock position (see FIG. 3B).

The latch mechanism 122 having the above-described configuration can fix a left portion of the lid 102 to the FOUP body 101 when the rotary plate 131 is in the lock position (see FIG. 3A). The latch mechanism 122 can release the left portion of the lid 102 from the FOUP body 101 when the rotary plate 131 is in the unlock position (see FIG. 3B).

The latch mechanism 123 is provided in a right portion of the lid body 121. Since the latch mechanism 123 has the same configuration as the latch mechanism 122 except for an arrangement position in the left-right direction, the following description will be made relatively simple. The latch mechanism 123 includes a rotary plate 141, the locking plate 142, and the locking plate 143. The rotary plate 141 is provided correspondingly to the opening 125. The rotary plate 141 has a keyhole 144 into which a latch key 66 (a key in the present disclosure), which will be described later, is inserted. The rotary plate 141 has a front cam 145 formed in an upper portion and a front cam 146 formed in a lower portion. The rotary plate 141 can rotate between a lock position (see FIG. 3A) and an unlock position (see FIG. 3B). The locking plate 142 is connected to the rotary plate 141 via a cam follower 147. An engagement claw 142a to be inserted into the engagement hole 116 is formed in an upper end portion of the locking plate 142. The locking plate 143 is connected to the rotary plate 141 via a cam follower 148. An engagement claw 143a to be inserted into the engagement hole 117 is formed in a lower end portion of the locking plate 143.

The latch mechanism 123 having the above-described configuration can fix a right portion of the lid 102 to the FOUP body 101 when the rotary plate 141 is in the lock position (see FIG. 3A). The latch mechanism 123 can release the right portion of the lid 102 from the FOUP body 101 when the rotary plate 141 is in the unlock position (see FIG. 3B).

### Load Port

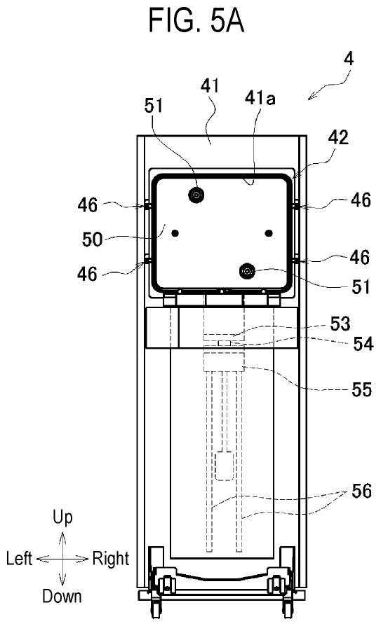

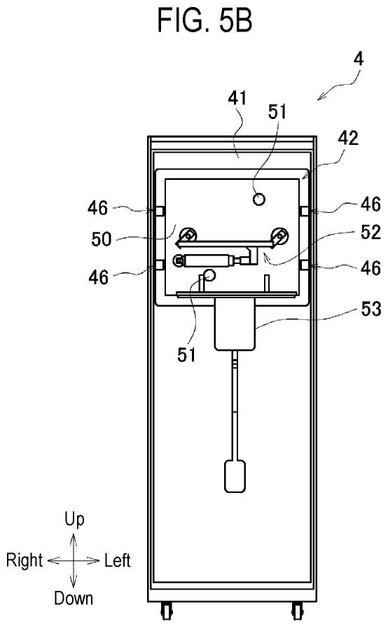

Next, the configuration of the load port 4 will be described with reference to FIGS. 4A to 5B. FIG. 4A is a perspective view of the load port 4. FIG. 4B is a right side view of the load port 4. FIG. 5A is a front view of the load port 4. FIG. 5B is a rear view of the load port 4.

As described above, the load port 4 is configured to place the FOUP 100 thereon, and is also configured to attach and detach the lid 102 with respect to the FOUP body 101 of the FOUP 100 placed thereon. The load port 4 includes a base 41 (a partition wall in the present disclosure), a door mechanism 42, a support frame 43, a stage 44, an air cylinder 45, a plurality of clamp mechanisms 46, and the controller 47.

The base 41 is a flat plate member having a substantially rectangular shape when viewed in the front-rear direction. The base 41 is disposed to extend in the up-down direction. The base 41 constitutes at least a portion of a partition wall that separates the transfer space 9 from the external space 10. An opening 41a having a substantially rectangular shape when viewed in the front-rear direction is formed in an upper portion of the base 41. The opening 41a has a size that allows the lid 102 of the FOUP 100 to pass through the opening 41a in the front-rear direction. Further, the opening 41a has a size that can be opened and closed by a door body 50 to be described later. The base 41 is formed of, for example, a sheet metal.

The door mechanism 42 is configured to adsorb and hold the lid 102, lock and unlock the lid 102, and move the lid 102. A more specific configuration of the door mechanism 42 will be described later.

The support frame 43 is a member for supporting the stage 44. The support frame 43 has a substantially rectangular shape when viewed in the up-down direction. The support frame 43 is fixed to the base 41. The support frame 43 is disposed to protrude forward from a midpoint of the base 41 in the up-down direction.

The stage 44 is a table-like member on which the FOUP 100 is placed. The stage 44 is supported by the support frame 43. The stage 44 is configured to be movable in the front-rear direction with respect to the support frame 43. The stage 44 is configured to be movable between a delivery position where the FOUP 100 can be delivered to and from a FOUP transfer device (not shown) and a lid opening/closing position located rearward of the transfer position. The stage 44 is provided with positioning pins 44a, a locking claw 44b, a gas injection nozzle 44c, and a gas exhaust nozzle 44d. The positioning pins 44a are members for positioning the FOUP 100. The locking claw 44b is a member for fixing (locking) and releasing (unlocking) the FOUP 100 with respect to the stage 44. The gas injection nozzle 44c is a nozzle for supplying an inert gas to the internal space Sf of the FOUP 100. The gas injection nozzle 44c is connected to an inert gas supply port (not shown) via a valve 44e. The gas injection nozzle 44c is configured to be connectable to a gas supply valve 118. The gas exhaust nozzle 44d is a nozzle for exhausting a gas from the internal space Sf of the FOUP 100. The gas exhaust nozzle 44d is connected to a gas exhaust port (not shown) via a valve 44f. The gas exhaust nozzle 44d is configured to be connectable to a gas exhaust valve 119.

The air cylinder 45 is configured to move the stage 44 in the front-rear direction. The air cylinder 45 includes a cylinder body (not shown) and a piston rod (not shown). A compressed air is supplied to and discharged from the cylinder body. The piston rod is disposed to extend and contract in the front-rear direction, and extends and contracts by an action of the compressed air. The air cylinder 45 functions as a bias that biases the stage 44 rearward when the stage 44 is located at the lid opening/closing position.

The clamp mechanisms 46 are configured to grip the FOUP 100 to bring the FOUP 100 into close contact with the base 41.

The controller 47 includes a central processing unit (CPU), a read only memory (ROM), a random access memory (RAM), and the like, which are not shown. The controller 47 controls individual mechanisms of the load port 4 by the CPU according to a program stored in the ROM. Further, the controller 47 communicates with the control device 5 of the EFEM 3.

### Configuration of Door Mechanism

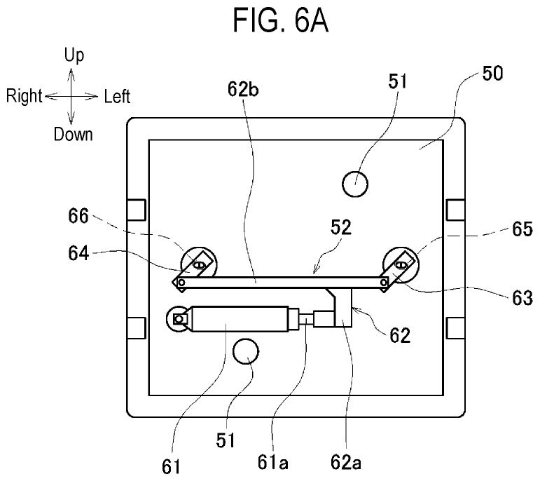

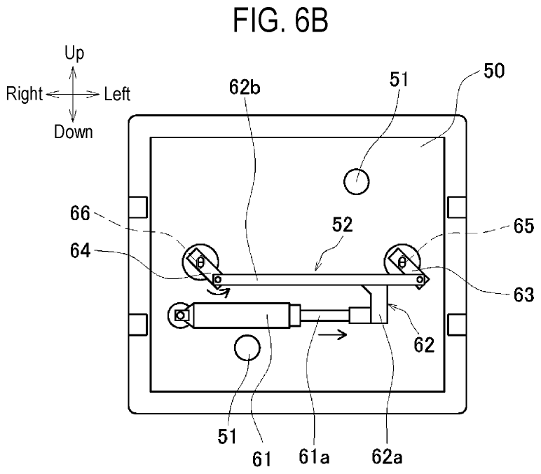

A configuration of the door mechanism 42 will be described with reference to FIGS. 4A to 6B. FIGS. 6A and 6B are rear views of a key locking/unlocking mechanism 52, which will be described later. FIG. 6A is an explanatory view showing a state of the key locking/unlocking mechanism 52 when the rotary plates 131 and 141 are in the lock positions (see FIG. 3A). FIG. 6B is an explanatory view showing a state of the key locking/unlocking mechanism 52 when the rotary plates 131 and 141 are in the unlock positions (see FIG. 3B).

As shown in FIG. 4B, the door mechanism 42 includes the door body 50, a plurality of adsorption holders 51 (holders in the present disclosure), the key locking/unlocking mechanism 52, a door support 53, a guide rail 54, a lifting block 55, a guide rail 56, a motor 57 (mover in the present disclosure), and a motor 58. The door body 50 is a plate-like member having a substantially rectangular shape when viewed in the front-rear direction. The door body 50 has a front end surface 50a that can face the end surface 121a of the lid body 121 in the front-rear direction. An imaginary plane P including the front end surface 50a corresponds to an imaginary plane in the present disclosure. The door body 50 is supported by the door support 53.

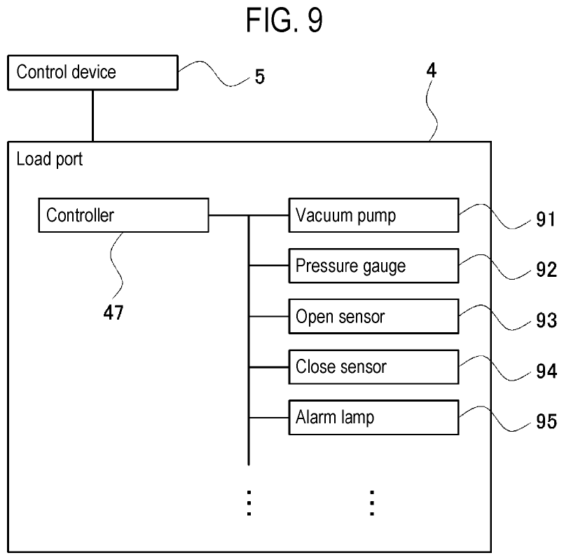

The adsorption holders 51 serve to adsorb and hold the lid 102 on the door body 50. Each of the adsorption holders 51 is formed in the front end surface 50a of the door body 50. The adsorption holders 51 are connected to a vacuum pump 91 (see FIG. 9) via pipes (not shown). When the vacuum pump 91 operates, a negative pressure is generated inside the pipes, and the lid 102 is adsorbed and held by the door body 50.

The key locking/unlocking mechanism 52 is configured to lock and unlock the lid 102 (more specifically, the latch mechanisms 122 and 123). As shown in FIGS. 6A and 6B, the key locking/unlocking mechanism 52 includes, for example, an air cylinder 61, a moving member 62, arms 63 and 64, and latch keys 65 and 66. The air cylinder 61 includes, for example, a piston rod 61a that can extend and contract in the left-right direction. The piston rod 61a is switched between a standby state (see FIG. 6A) and a protruding state (see FIG. 6B) according to supplying a compressed air to the air cylinder 61 or discharging the compressed air from the air cylinder 61. The moving member 62 is fixed to a tip end portion of the piston rod 61a and moves in the left-right direction together with the piston rod 61a. The moving member 62 includes a first member 62a protruding upward from the air cylinder 61, and a second member 62b fixed to an upper end portion of the first member 62a. The second member 62b is a rod-shaped member extending in the left-right direction. The arm 63 is swingably attached to a left end portion of the second member 62b. The arm 64 is swingably attached to a right end portion of the second member 62b. The latch key 65 is fixed to a tip end portion of the arm 63 and is rotatably supported by the door body 50. The latch key 66 is fixed to a tip end portion of the arm 64 and is rotatably supported by the door body 50. When the piston rod 61a is in the standby state, the latch keys 65 and 66 can be inserted into the keyholes 134 and 144 (see FIG. 2), respectively. By switching the state of the piston rod 61a between the standby state and the protruding state, the latch keys 65 and 66 can rotate the rotary plates 131 and 141 between the lock position (see FIG. 3A) and the unlock position (see FIG. 3B), respectively.

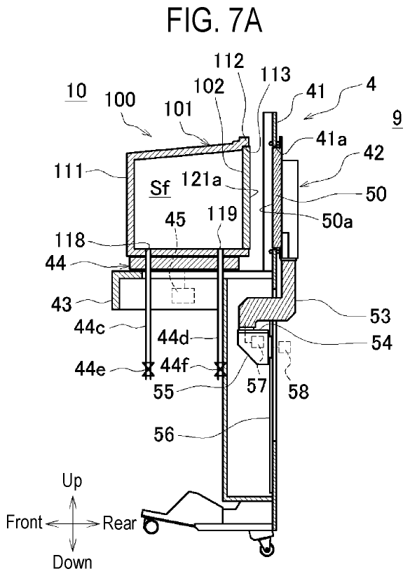

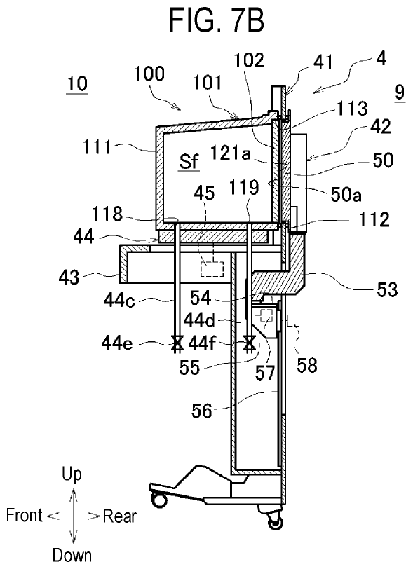

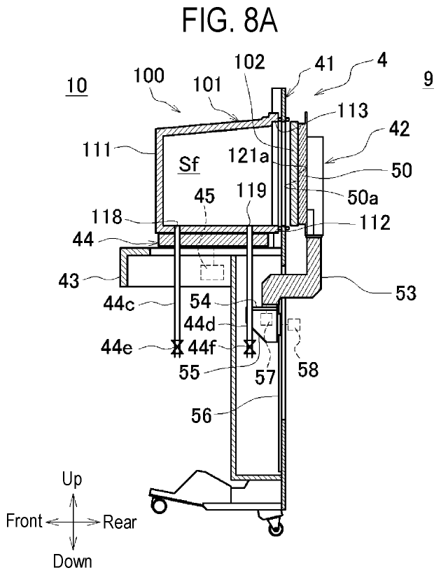

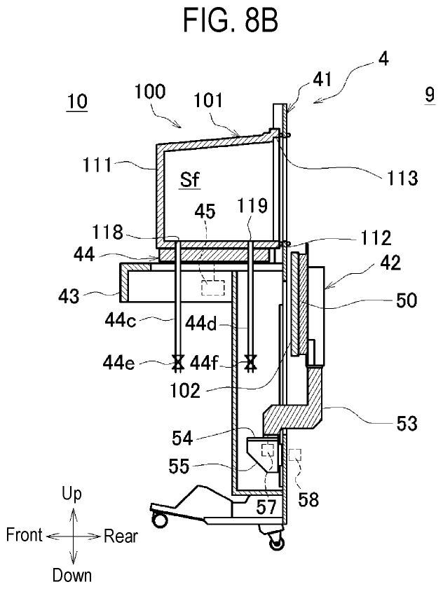

The door support 53 is a member that supports the door body 50. The door support 53 is disposed in the transfer space 9 and outside a movable range of the transfer robot 3. The door body 50 is fixed to the door support 53 by a fixing device (not shown). The door support 53 extends in the up-down direction. The door support 53 is supported by the guide rail 54 so that the door support 53 can move in the front-rear direction. The door support 53 is driven by the motor 57 to move in the front-rear direction. By moving in the front-rear direction, the door support 53 moves the door body 50 between a closing position (see FIG. 7B) and an opening position (see FIG. 8A). The closing position is a position of the door body 50 when the door body 50 blocks the opening 41a of the base 41. The opening position is a position of the door body 50 when the door body 50 opens the opening 41a.

The guide rail 54 is a member that guides the door support 53 in the front-rear direction. The guide rail 54 is provided on the lifting block 55. The guide rail 54 extends in the front-rear direction.

The lifting block 55 is a member for moving the door body 50 in the up-down direction. The lifting block 55 is disposed in the transfer space 9 and outside the movable range of the transfer robot 3. The lifting block 55 movably supports the door support 53 by the guide rail 54. The lifting block 55 is guided in the up-down direction along the guide rail 56. The lifting block 55 is driven by the motor 58 to move in the up-down direction. By moving in the up-down direction, the lifting block 55 moves the door body 50 between the above-described opening position and a retracted position (see FIG. 7B) lower than the opening position.

The guide rail 56 is a member that guides the lifting block 55 in the up-down direction. The guide rail 56 is provided on the base 41. The guide rail 56 extends in the up-down direction.

The motor 57 is configured to drive the door support 53 to move in the front-rear direction. The motor 57 is, for example, a well-known stepping motor. The motor 57 is configured to control a position of the door supports 53 in the front-rear direction.

The motor 58 is configured to drive the lifting block 55 to move in the up-down direction. The motor 58 is, for example, a well-known stepping motor. The motor 58 is configured to control a position of the door support 53 in the up-down direction.

Operations of the load port 4 having the configuration described above will be described with reference to FIGS. 7A to 8B. FIGS. 7A to 8B are right side views of the load port 4 during operations. Here, operations of the load port 4 from when the FOUP 100 is placed on the stage 44 to when the lid 102 is separated from the FOUP body 101 by the door mechanism 42 will be described.

First, the FOUP 100 is placed on the stage 44 (see FIG. 7A). At this time, the FOUP 100 is positioned by the positioning pins 44a and fixed to the stage 44 by the locking claw 44b. In addition, the gas injection nozzle 44c is connected to the gas supply valve 118, and the gas exhaust nozzle 44d is connected to the gas exhaust valve 119.

The controller 47 controls an operation of the air cylinder 45 to move the stage 44 from the delivery position (see FIG. 7A) to the lid opening/closing position (see FIG. 7B). As a result, the end surface 121a of the lid 102 faces the front end surface 50a of the door body 50 at a position near the front end surface 50a in the front-rear direction. At this time, the latch keys 65 and 66 (see FIG. 4A) are inserted into the keyholes 134 and 144 (see FIG. 2), respectively. Subsequently, the controller 47 controls the valves 44e and 44f to supply an inert gas (a second gas in the present disclosure) to the internal space Sf of the FOUP 100, while discharging a gas (a first gas in the present disclosure) filling the internal space Sf from the internal space Sf. As a result, the gas in the internal space Sf is replaced with the inert gas (this process is also generally called a purging process). When the purging process is being performed, a pressure in the FOUP 100 becomes higher than a pressure in the external space 10, and the lid 102 may be pushed slightly outward (more specifically, rearward). The purging process may be performed before the stage 44 moves to the lid opening/closing position.

Subsequently, the controller 47 controls the clamp mechanism 46 to press the FOUP 100 against the base 41. Subsequently, the controller 47 controls the vacuum pump 91 to adsorb and hold the lid 102 on the adsorption holder 51 of the door body 50. Further, the controller 47 controls an operation of the key locking/unlocking mechanism 52 to unlock the latch mechanisms 122 and 123. Subsequently, the controller 47 controls the motor 57 to move the door body 50 from the closing position (see FIG. 7B) to the opening position (see FIG. 8A). Thus, the lid 102 is separated from the FOUP body 101. For the sake of convenience of description, the above-described process (step) of unlocking the latch mechanisms 122 and 123 while the lid 102 is held by the adsorption holder 51 and moving the door body 50 from the closing position to the opening position by the motor 57 for the first time is called an opening process (opening step).

By the opening process, the internal space Sf and the transfer space 9 are connected to each other via the opening 113 and the opening 41a. The internal space Sf and the transfer space 9 are separated from the external space 10 by the base 41 or the like. After the opening process, the controller 47 controls the motor 58 to move the door body 50 from the opening position to the retracted position (see FIG. 8B). Thus, the wafer W can be delivered between the internal space Sf and the transfer space 9. In other words, the wafer W can be delivered between the internal space Sf and the processing apparatus 6. By the processing apparatus 6, predetermined processes are performed sequentially for all (or a part) of the wafers W. The processed wafers W are returned to the internal space Sf.

After the processes for the wafer W are completed, the controller 47 causes the door mechanism 42 and the like to perform a reverse operation to the operation of opening the lid 102. That is, the controller 47 moves the door body 50 from the retracted position to the opening position, and further moves the door body 50 from the opening position to the closing position. Subsequently, the controller 47 controls an operation of the key locking/unlocking mechanism 52 to lock the lid 102. The above-described process (step) of returning the door body 50 to the closing position with the lid 102 held by the adsorption holder 51 and locking the latch mechanisms 122 and 123 after the opening process corresponds to a closing process (closing step) in the present disclosure.

In addition, the controller 47 performs the above-described purging process again. The controller 47 releases the adsorption of the lid 102 to the door body 50 (attracting release). Thereafter, the controller 47 moves the stage 44 from the lid opening/closing position to the delivery position.

Here, when the FOUP 100 is transferred to another location without closing the lid 102 normally, the lid 102 may fall off from the FOUP body 101 during the transfer of the FOUP 100. Further, wafers contained in the FOUP 100 may fall off from the FOUP 100. Thus, various methods for checking whether or not the lid 102 is normally closed have been studied. However, according to the conventional methods, erroneous determination may be made, or the internal space Sf of the FOUP 100 may be exposed to the gas (the air) of the external space 10. In the present embodiment, the load port 4 further has the following configuration. In addition, in order to effectively check whether or not the lid 102 is normally closed in the FOUP 100 without exposing the internal space Sf to the gas of the external space 10, a control to be described later is performed in the present embodiment.

First, a configuration for determining whether or not the lid 102 is normally closed will be described with reference to the block diagram of FIG. 9.

As shown in FIG. 9, the load port 4 includes the above-described vacuum pump 91. The vacuum pump 91 is for adsorbing and holding the lid 102 on the door body 50 by a negative pressure generated in a vicinity of the adsorption holder 51. The load port 4 further includes a pressure gauge 92, an open sensor 93 (an information acquisitor and an open detector in the present disclosure), a close sensor 94, and an alarm lamp 95. The pressure gauge 92 is used to determine whether or not the negative pressure is normally generated in the vicinity of the adsorption holder 51. The pressure gauge 92 is provided, for example, in a pipe (not shown) that connects the adsorption holder 51 and the vacuum pump 91, and is configured to measure a pressure in the pipe. The open sensor 93 is configured to detect information on whether or not the door body 50 is located in the opening position. The close sensor 94 is configured to detect information on whether or not the door body 50 is located in the closing position. The alarm lamp 95 is a lamp configured to issue an alarm. The vacuum pump 91, the pressure gauge 92, the open sensor 93, the close sensor 94, and the alarm lamp 95 are electrically connected to the controller 47.

### Lid Closed State Determination Method

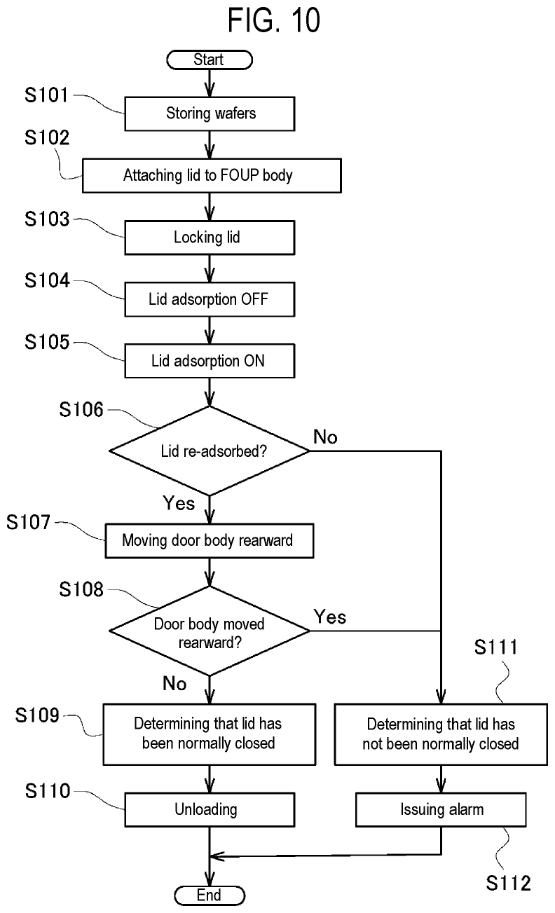

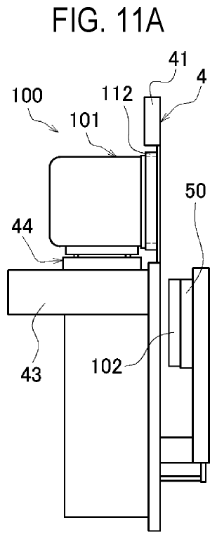

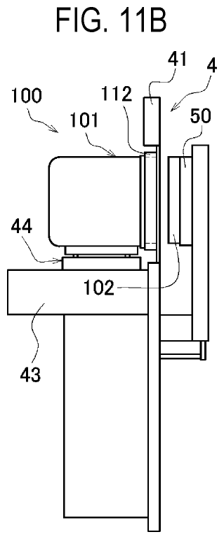

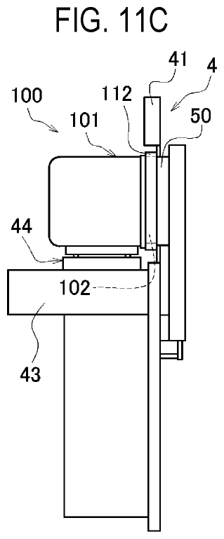

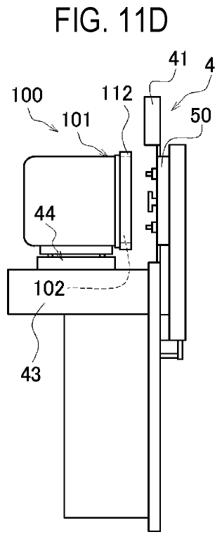

Next, a method of determining a closed state of the lid 102 (closed state determination method) will be described with reference to the flowchart of FIG. 10 and FIGS. 11A to 11D. FIGS. 11A to 11D are explanatory views showing an operation of the load port 4. The determination of the closed state of the lid 102 is performed by the controller 47.

In an initial state, the FOUP 100 is placed on the stage 44. The lid 102 is adsorbed and held on the door body 50. The door body 50 is located in the retracted position. In other words, the initial state is a state after the above-described opening process (opening step) has already been executed.

In this state, the control device 5 (see FIG. 9) controls the transfer robot 3 to store all the wafers W taken out from the FOUP 100 in the FOUP body 101 (S101). Thereafter, the control device 5 communicates with the controller 47 and transmits an instruction signal to the controller 47 to start a process of attaching the lid 102 to the FOUP body 101.

After receiving the instruction signal, the controller 47 controls the door mechanism 42 to move the door body 50 to the closing position (S102). More specifically, the controller 47 controls the motor 58 to move the door body 50 from the retracted position (see FIG. 11A) to the opening position (see FIG. 11B). Further, the controller 47 controls the motor 57 to move the door body 50 from the opening position to the closing position (see FIG. 11C). Thus, the lid 102 moves to a position where the lid 102 closes the opening 113 of the FOUP body 101. Completion of moving the door body 50 to the closing position is determined based on a detection result of the close sensor 94. Subsequently, the controller 47 controls the key locking/unlocking mechanism 52 so that the latch keys 65 and 66 operate to rotate the rotary plates 131 and 141, respectively, from the unlock position to the lock position. As a result, the lid 102 is locked (S103). That is, the above-described closing process (closing step) is executed.

Subsequently, the controller 47 controls the vacuum pump 91 to stop adsorbing and holding the lid 102 by the adsorption holder 51 (S104).

Subsequently, the controller 47 controls the vacuum pump 91 to cause the adsorption holder 51 to adsorb and hold the lid 102 again (S105). The controller 47 determines whether or not the lid 102 has been re-adsorbed to the adsorption holder 51 (S106). When the pressure measured by the pressure gauge 92 becomes equal to or lower than a predetermined reference pressure within a predetermined time, the controller 47 determines that the lid 102 has been normally re-adsorbed to the adsorption holder 51 (S106: “Yes”). When the pressure does not become equal to or lower than the reference pressure even after the predetermined time has elapsed, the controller 47 determines that the lid 102 has not been normally re-adsorbed to the adsorption holder 51 (S106: “No”).

When the lid 102 is normally re-adsorbed to the adsorption holder 51, the controller 47 controls the door mechanism 42 (motor 57) to move the door body 50 rearward while the adsorption holder 51 holds the lid 102 (S107). The controller 47 determines whether or not the door body 50 has retreated based on a detection result of the open sensor 93 (S108). When a signal indicating that the door body 50 is in the opening position is received from the open sensor 93 within a predetermined time from starting the control for moving the door body 50 rearward, the controller 47 determines that the door body 50 has moved rearward (S108: “Yes”). When the signal is not received from the open sensor 93 even after the predetermined time has elapsed from starting the control for moving the door body 50 rearward, the controller 47 determines that the door body 50 has not moved rearward (S108: “No”).

When the door body 50 has not moved rearward, the controller 47 determines that the lid 102 has been normally closed (S109). Thereafter, the controller 47 moves the stage 44 from the lid opening/closing position to the delivery position (see FIG. 11D). The controller 47 releases fixing the FOUP 100 to the stage 44 by the locking claw 44b. Thus, it is possible to transfer the FOUP 100 from the load port 4 to the FOUP transfer device (unloading) (S110).

On the other hand, when the lid 102 is not normally re-adsorbed to the adsorption holder 51, or when the door body 50 has moved rearward from the closing position to the opening position, the controller 47 determines that the lid 102 is not normally closed in the FOUP body 101 (S111). In this case, the controller 47 controls the alarm lamp 95 to issue an alarm (S112). Thus, it is possible to notify an operator that abnormality has occurred in the load port 4.

As described above, the controller 47 controls the motor 57 to move the door body 50 from the closing position back to the opening position, and determines whether or not the lid 102 has been normally closed based on the information acquired by the open sensor 93. The above-described process (step) performed after the closing process (closing step) corresponds to a checking process (checking step) in the present disclosure.

As described above, by performing, with respect to the FOUP 100, a checking process of pulling the lid 102 by the door body 50, it is possible to check whether or not the lid 102 is normally closed after the closing process. Further, since such checking is performed without moving the FOUP 100, it is possible to prevent the internal space Sf of the FOUP 100 from being exposed to the gas of the external space 10. Therefore, it is possible to effectively check whether or not the lid 102 of the FOUP 100 is normally closed without exposing the internal space Sf to the gas of the external space 10.

Further, in the opening process, whether or not the door body 50 has normally reached the opening position can be determined by using the open sensor 93. Furthermore, the checking process can also be performed by using the open sensor 93. That is, the open sensor 93 can be used for both the opening process and the checking process. Therefore, compared to a case where the checking process is performed using the open sensor 93 and components other than the open sensor 93, an increase in the number of components constituting the load port 4 can be suppressed.

Next, modifications of the above-described embodiment will be described. In the modifications, the same reference numerals will be designated to parts having similar configurations to those in the above-described embodiment, and description thereof will be omitted as appropriate.
(1) In the above-described embodiment, after the closing process (closing step), the controller 47 controls the vacuum pump 91 to stop adsorbing and holding the lid 102 by the adsorption holder 51. However, the present disclosure is not limited thereto. After the closing process (closing step), the controller 47 may start the checking process (checking step) in a state in which the adsorption holder 51 is maintained to adsorb and hold the lid 102.
(2) The door mechanism 42 may be configured to change a magnitude of thrust applied to the door body 50 by the motor 57. For example, the motor 57 itself may be configured to change an output thereof. Alternatively, a transmission mechanism (not shown) that transmits the output of the motor 57 to the door body 50 may be provided, and the transmission mechanism may be configured to change a force transmitted from the motor 57 to the door body 50. In this case, the motor 57 and the transmission mechanism correspond to the mover in the present disclosure. The controller 47 may apply a predetermined first thrust to the door body 50 when the opening process is performed (i.e., when the lid 102 is removed from the FOUP body 101 for the first time). In addition, the controller 47 may apply a second thrust weaker than the first thrust to the door body 50 when the checking process is performed. With this configuration, it is possible to suppress the thrust applied to the door body 50 from becoming too strong during the checking process. Accordingly, it is possible to prevent the engagement claws 132a, 133a, 142a, and 143a from being damaged during the checking process.
(3) When determining that the door body 50 has moved rearward in the checking process (checking step), the controller 47 may execute the following re-closing process (re-closing step). That is, the controller 47 may operate the latch mechanisms 122 and 123 to move the engagement claws 132a, 133a, 142a, and 143a from the engaged positions to the released positions by the latch keys 65 and 66 in a state in which the lid 2 is held by the adsorption holder 51. Further, the controller 47 may cause the door body 50 to return to the closing position by the motor 57, and operate the latch mechanisms 122 and 123 to move the engagement claws 132a, 133a, 142a, and 143a from the released positions to the engaged positions by the latch keys 65 and 66. The above-described re-closing process (re-closing step) may be executed. With this configuration, even when the closing process fails once, no action by the operator is required when the re-closing process is successful. Therefore, an increase in operator's workload can be suppressed. In addition, the controller 47 may execute the checking process (checking step) again after the re-closing process (re-closing step).
(4) In the above-described modification (3), the controller 47 may repeatedly perform the re-closing process and the checking process (hereinafter, these processes are collectively referred to as retry process) until it is determined that the lid 102 is normally locked. The controller 47 may be configured to set in advance a maximum number of execution times of the retry process. When it is determined that the lid 102 is still not normally locked even after the number of execution times of the retry process reaches the maximum number of execution times, the controller 47 may control the alarm lamp 95 to issue an alarm.
(5) In the above-described embodiment, the controller 47 determines, in the checking process, the closed state of the lid 102 based on the detection result obtained by the open sensor 93. However, the present disclosure is not limited thereto. The controller 47 may determine, in the checking process, the closed state of the lid 102 based on the detection result obtained by the close sensor 94. For example, in the checking process, the controller 47 may determine that the lid 102 is not normally closed when a signal indicating that the door body 50 has been spaced apart from the closing position is transmitted from the close sensor 94 to the controller 47.

Alternatively, the closed state of the lid 102 may be determined by using a means other than the open sensor 93 and the close sensor 94. For example, the motor 57 may have a rotary encoder (not shown). In the checking process, the controller 47 may determine whether or not the door body 50 has moved (i.e., determine the closed state of the lid 102) based on a signal received from the rotary encoder. Alternatively, another means for detecting information related to a position of the door body 50 may be provided.
(6) The load port 4 may include a means for detecting whether or not the engagement claws 132a, 133a, 142a, and 143a are damaged during the checking process. The load port 4 may have, for example, a microphone (not shown) disposed in a vicinity of the opening 41a. The controller 47 may make determination based on sound data detected by the microphone during the checking process. More specifically, the controller 47 may store a learning model, which is constructed in advance by, for example, machine learning and is used for estimating whether or not the engagement claws 132a, 133a, 142a, and 143a are creaking. The controller 47 may determine whether or not the engagement claws 132a, 133a, 142a, and 143a are damaged by estimation using the learning model. Alternatively, the learning model may be stored in the control device 5.
(7) The keyholes 134 and 144 provided in the lid 102 may be worn and enlarged due to, for example, deterioration over time. In that case, the latch mechanisms 122 and 123 may not be operated normally by the latch keys 65 and 66, and the lid 102 may not be locked normally. Since it is not desirable to use a FOUP 100 having such a lid 102 continuously, it is necessary to find such a FOUP 100. In addition, when a trend of a correlation between a period of use of the FOUP 100 and a frequency of determining that the lid 102 is not closed normally can be recognized, it can be useful for making a decision to stop using an old FOUP 100. Therefore, the load port 4 may be configured to acquire entity information of the FOUP 100 and various information (e.g., a type of the FOUP 100, a year of use, and the like) associated with the entity information. More specifically, the load port 4 may have a reader (not shown) capable of reading an ID tag (not shown) attached to the FOUP 100. Alternatively, for example, the control device 5 may be configured to communicate with a host computer (not shown) capable of managing a transfer status of the FOUP 100. The control device 5 may communicate with the host computer to acquire the entity information of the FOUP 100 and various information associated with the entity information. The control device 5 may communicate with the controller 47 to store information on a result of the checking process for a specific FOUP 100 in association with entity information of the FOUP 100. The control device 5 may transmit the information on the result of the checking process associated with the entity information of the FOUP 100 to the host computer. By using such information, it is possible to efficiently find a FOUP 100 having a defective lid 102. In addition, it is possible to recognize a trend of a type and/or a period of use of a FOUP 100 that becomes defective easily.
(8) In the above-described embodiment, the door body 50 is driven by the motor 57 to move in the front-rear direction, and the stage 44 is driven by the air cylinder 45 to move in the front-rear direction. However, a moving means for moving the door body 50 and the stage 44 is not limited thereto.
(9) In the above-described embodiment, the load port 4 is configured to perform the purging process. However, the present disclosure is not limited thereto. The load port 4 may not have the configuration for performing the purging process.
(10) In the above-described embodiment, the load port 4 includes the controller 47. However, the present disclosure is not limited thereto. For example, the control device 5 of the EFEM 3 may control the load port 4.
(11) As an inert gas, a gas other than nitrogen gas may be injected into the FOUP 100. A container placed on the load port 4 is not limited to the FOUP 100. For example, a front opening shipping box (FOSB) for transporting substrates between factories may be placed on the load port 4. The load port 4 may be placed on equipment other than the EFEM 3.

### EXPLANATION OF REFERENCE NUMERALS

4: load port, 9: transfer space, 10: external space, 41: base (partition wall), 41a: opening, 42: door mechanism, 47: controller, 50: door body, 51: adsorption holder (holder), 57: motor (mover), 65: latch key (key), 66: latch key (key), 93: open sensor (information acquisitor or open detector), 101: FOUP body (container body), 102: lid, 113: opening (side opening), 122: latch mechanism (locking mechanism), 123: latch mechanism (locking mechanism), Sf: internal space, W: wafer (transfer target)

1-5. (canceled)

6. A load port comprising:
a partition wall configured to connect an internal space of a container body, which has a side opening formed on a side surface of the container body and accommodates a transfer target, to a transfer space in which transfer of the transfer target is performed, wherein the partition wall has an opening through which a lid for opening and closing the side opening can pass, and is configured to separate the internal space and the transfer space from an external space;
a door mechanism configured to attach and detach the lid with respect to the container body; and
a controller,
wherein the door mechanism comprises:
a door body configured to open and close the opening of the partition wall;
a holder configured to hold the lid on the door body;
a key configured to lock and unlock a locking mechanism provided on the lid to cause the lid to engage with the container body;
a mover configured to move the door body between a closing position where the door body closes the opening of the partition wall and an opening position where the door body opens the opening of the partition wall; and
an information acquisitor configured to acquire information on a position of the door body, and
wherein the controller performs:
a closing process of moving the door body to the closing position by the mover in a state in which the lid is held by the holder, and locking the locking mechanism by the key; and
after the closing process, a checking process of moving the door body from the closing position to the opening position in a state in which the lid is held by the holder, and determining whether or not the lid is normally closed based on the information acquired by the information acquisitor.

7. The load port of claim 6, wherein the information acquisitor includes an open detector configured to detect whether or not the door body is located at the opening position, and
wherein in the checking process, the controller determines that the lid is not normally closed when information indicating that the door body is located at the opening position is detected by the open detector.

8. The load port of claim 7, wherein the mover is configured to change a thrust for moving the door body, and
wherein the controller applies a predetermined first thrust to the door body when performing an opening process of separating the lid from the container body, and applies a second thrust weaker than the first thrust to the door body when performing the checking process.

9. The load port of claim 7, wherein when determining that the lid is not normally closed in the checking process, the controller performs a re-closing process of unlocking the locking mechanism by the key in a state in which the lid is held by the holder, causing the door body to return to the closing position by the mover, and locking the locking mechanism by the key.

10. The load port of claim 6, wherein the mover is configured to change a thrust for moving the door body, and
wherein the controller applies a predetermined first thrust to the door body when performing an opening process of separating the lid from the container body, and applies a second thrust weaker than the first thrust to the door body when performing the checking process.

11. The load port of claim 6, wherein when determining that the lid is not normally closed in the checking process, the controller performs a re-closing process of unlocking the locking mechanism by the key in a state in which the lid is held by the holder, causing the door body to return to the closing position by the mover, and locking the locking mechanism by the key.

12. A lid closed state determination method of determining whether or not a lid is normally closed in a load port that attaches and detaches, with respect to a container body accommodating a transfer target, the lid for opening and closing a side opening formed on a side surface of the container body,
wherein the load port comprises:
a partition wall configured to connect an internal space of the container body to a transfer space in which transfer of the transfer target is performed, wherein the partition wall has an opening through which the lid can pass, and is configured to separate the internal space and the transfer space from an external space; and
a door mechanism configured to attach and detach the lid with respect to the container body,
wherein the door mechanism comprises:
a door body configured to open and close the opening of the partition wall;
a holder configured to hold the lid on the door body;
a key configured to lock and unlock a locking mechanism provided on the lid to cause the lid to engage with the container body;
a mover configured to move the door body between a closing position where the door body closes the opening of the partition wall and an opening position where the door body opens the opening of the partition wall; and
an information acquisitor configured to acquire information on a position of the door body, and
wherein the method comprises:
a closing process of moving the door body to the closing position by the mover in a state in which the lid is held by the holder, and locking the locking mechanism by the key; and
after the closing process, a checking process of moving the door body from the closing position to the opening position in a state in which the lid is held by the holder, and determining whether or not the lid is normally closed based on the information acquired by the information acquisitor.
